(19) United States
(12) Patent Application Publication
(10) Pub. No.: US 2024/0014064 A1
(43) Pub. Date: Jan. 11, 2024

(54) SEMICONDUCTOR MANUFACTURING APPARATUS INCLUDING NON-CONTACT COMMUNICATION DEVICES

(71) Applicant: ASM IP Holding, B.V., Almere (NL)

(72) Inventor: Kohei Watanabe, Kawasaki-shi (JP)

(21) Appl. No.: 18/346,670

(22) Filed: Jul. 3, 2023

Related U.S. Application Data
(60) Provisional application No. 63/358,285, filed on Jul. 5, 2022.

(51) Int. Cl. H01L 21/68; H01L 21/677

(52) U.S. Cl. CPC H01L 21/681; H01L 21/6773

(57) ABSTRACT

Examples of a semiconductor manufacturing apparatus includes a first housing, at least one first communication device fixed to the first housing and having a first non-contact communication surface exposed from the first housing, a second housing fixed to the first housing, and at least one second communication device fixed to the second housing and having a second non-contact communication surface exposed from the second housing. The first non-contact communication surface and the second non-contact communication surface oppose each other without contacting each other.

### CROSS REFERENCE TO RELATED APPLICATION

This application claims the benefit of U.S. Provisional Application 63/358,285 filed on Jul. 5, 2022, the entire contents of which are incorporated herein by reference.

### FIELD

Examples are described which relates to a semiconductor manufacturing apparatus including non-contact communication devices.

### BACKGROUND

For example, a semiconductor manufacturing apparatus responsible for substrate conveyance and substrate processing has a complicated configuration, and is significantly large as a whole. The semiconductor manufacturing apparatus requires a large number of wiring connection operations in an assembly process. Such a large number of wiring operations per se prevent productivity from being improved. Further, a connection error may occur at the time of the wiring operations. Wiring connections at high or low positions, if included in such a large number of wiring operations, lead to poor operability for a worker.

### SUMMARY

Some examples described herein may address the above-described problems. Some examples described herein may provide a semiconductor manufacturing apparatus that facilitates assembly.

In some examples, a semiconductor manufacturing apparatus includes a first housing, at least one first communication device fixed to the first housing and having a first non-contact communication surface exposed from the first housing, a second housing fixed to the first housing, and at least one second communication device fixed to the second housing and having a second non-contact communication surface exposed from the second housing. The first non-contact communication surface and the second non-contact communication surface oppose each other without contacting each other.

### BRIEF DESCRIPTION OF THE DRAWINGS

FIG. 1 is a diagram illustrating an example of a configuration of a semiconductor manufacturing apparatus;

FIG. 2 is a diagram illustrating an example of the wiring connection;

FIG. 3A is a diagram illustrating an example of a wiring method;

FIG. 3B is a plan view of the first communication devices;

FIG. 3C is a diagram illustrating an example of the second communication device;

FIG. 4 is a diagram illustrating a state where the first non-contact surface and the second non-contact surface are brought into non-contact with and close to each other;

FIG. 5 is a diagram illustrating a method for connecting the ELEC BOX and the EFEM to each other;

FIG. 6 is a diagram illustrating an example in which non-contact communication devices are applied to an IO-Link system;

FIG. 7 is a diagram illustrating an example of non-contact communication devices;

FIG. 8 is a diagram illustrating another example of non-contact communication devices; and

FIG. 9 is a diagram illustrating an example of non-contact communication.

### DETAILED DESCRIPTION

A semiconductor manufacturing apparatus will be described with reference to the drawings. The same or corresponding components are respectively assigned the same reference numerals, and repeated descriptions may be omitted.

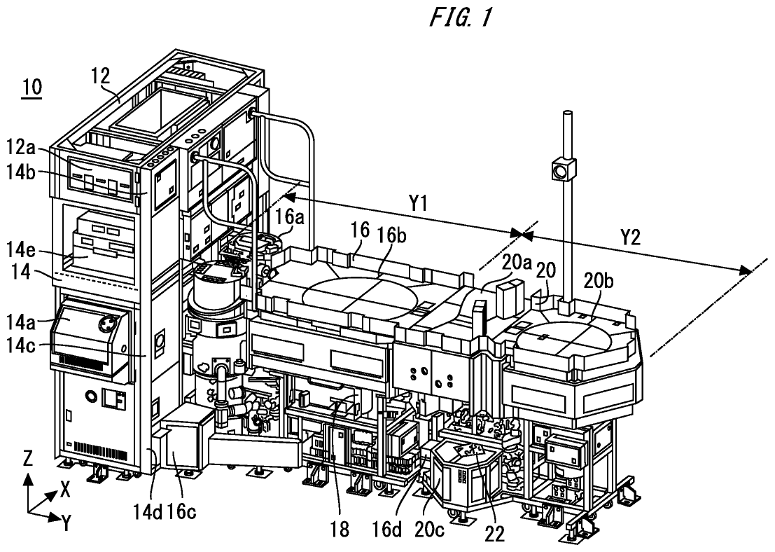

FIG. 1 is a diagram illustrating an example of a configuration of a semiconductor manufacturing apparatus. The semiconductor manufacturing apparatus includes an ELEC BOX 12. According to one example, the ELEC BOX 12 stores a plurality of controllers 12a such as a transfer module controller (TMC) and a process module controller (PMC). The TMC controls a substrate conveyance system, and the PMC controls a substrate processing process. In FIG. 1, the ELEC BOX 12 is surrounded by a solid line for convenience of illustration. The ELEC BOX 12 is supported by an equipment front end module (EFEM) 14, and is at a height of 180 cm or more from the ground, for example.

The EFEM 14 is an N2-equipment front end module (N2-EFEM), for example. The EFEM 14 is configured, for example, such that a plurality of devices are stored or fixed in one housing. The EFEM 14 includes a conveyance chamber 14a that conveys a substrate, for example. A wiring housing 14c storing a wiring for data communication and power supply is provided in addition to the conveyance chamber 14a. The wiring housing 14c is a vertically long box extending in a z-direction in the example illustrated in FIG. 1. According to one example, the wiring housing 14c has an upper portion 14b and a lower portion 14d, and ends of the wiring respectively exist in the upper portion 14b and the lower portion 14d.

According to one example, the EFEM 14 includes a fan filter unit (FFU) 14e on the conveyance chamber 14a. The FFU 14e generates a downflow of gas containing N₂ gas, for example, in the conveyance chamber 14a, to reduce an oxygen concentration in the conveyance chamber 14a.

A center module 16, for example, is provided beside the EFEM 14. According to one example, the center module 16 includes a load lock chamber (LLC) 16a and a first wafer handling chamber (WHC) 16b. According to one example, the LLC 16a is between the EFEM 14 and the first WHC 16b, and is screw-fixed thereto. According to one example, the LLC 16a is used when a wafer is moved between the conveyance chamber 14a and the first WHC 16b, as is well known.

According to one example, the center module 16 includes a wiring housing 16c. For example, the wiring housing 16c and the above-described lower portion 14d can be screw-fixed to each other with their respective openings opposing each other.

According to one example, a programmable logic box (PLC BOX) 18 is provided in the vicinity of the center module 16. According to one example, the PLC BOX 18 is fixed to a lower portion of the center module 16 or a position surrounded by the center module 16 by being screw-fixed to the center module 16. The PLC BOX 18 can manage safety TO of the entire platform.

A rear module 20 is provided beside the center module 16. The rear module 20 includes a pass-through chamber 20a and a second WHC 20b. The pass-through chamber 20a permits or inhibits movement of a wafer between the first WHC 16b and the second WHC 20b based on an instruction from a controller.

According to one example, an opening of a wiring housing 16d as a part of the center module 16 and an opening of a wiring housing 20c as a part of the rear module 20 are fixed to each other while they oppose each other. A utility box 22 is provided in a location below the rear module 20 or covered with the rear module 20. The utility box 22 can be screw-fixed to the rear module 20. The utility box 22 can store a sensor attached to the rear module 20, a power supply, and a remote IO unit for managing input/output information, for example.

Thus, the semiconductor manufacturing apparatus illustrated in FIG. 1 can be roughly divided into six blocks. That is, the semiconductor manufacturing apparatus illustrated in FIG. 1 includes the ELEC BOX 12, the EFEM 14, the center module 16, the PLC BOX 18, the rear module 20, and the utility box 22. In other words, the semiconductor manufacturing apparatus includes three modules, i.e., the EFEM 14, the center module 16, and the rear module 20 and three boxes, i.e., the ELEC BOX 12, the PLC BOX 18, and the utility box 22. The three modules can be mainly used to convey a wafer, and the three boxes can be used to control wafer processing and manage the apparatus. Although the semiconductor manufacturing apparatus to be roughly divided into six blocks is illustrated in the example illustrated in FIG. 1, another block configuration can be adopted according to another example.

According to one example, the assembly of the semiconductor manufacturing apparatus can be started once the above-described six blocks are individually completed or semi-completed. When the six blocks are each at least a semi-completed product, six sub-assemblies are obtained. In a semiconductor manufacturing apparatus manufacturing factory, the six sub-assemblies are docked to one another, to perform energization inspection. Then, the semiconductor manufacturing apparatus is disassembled to be easily conveyed to a client factory. According to one example, the semiconductor manufacturing apparatus is disassembled into three units, described below:
a first unit obtained by integrating the ELEC BOX 12 and the EFEM 14
a second unit obtained by integrating the center module 16 and the PLC BOX 18
a third unit obtained by integrating the rear module 20 and the utility box 22

According to another example, the semiconductor manufacturing apparatus can also be disassembled into six blocks, described above. The disassembled semiconductor manufacturing apparatus is conveyed to a client factory. This is delivery of a product. Then, in the client factory, a plurality of units or a plurality of blocks are docked to one another, to confirm energization of the semiconductor manufacturing apparatus, thereby completing the delivery.

Therefore, in both the manufacturing factory and the client factory, a wiring connection operation between sub-assemblies is required. When a large number of wiring connections are required for various data communication and power supply, an operation burden on a worker increases, and a wiring connection error is likely to occur. In the semiconductor manufacturing apparatus according to the present disclosure, at least some of the wiring connections are each implemented by a non-contact wiring, thereby significantly reducing the operation burden.

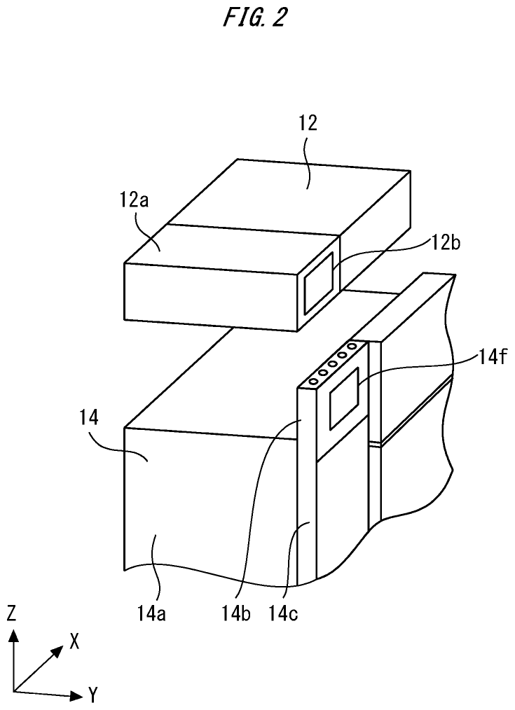

FIG. 2 is a diagram illustrating an example of the wiring connection. The assembly of the semiconductor manufacturing apparatus includes an operation for fixing the ELEC BOX 12 to the EFEM 14. The ELEC BOX 12 is placed on the EFEM 14 such that an opening 12b of the ELEC BOX 12 and an opening 14f provided in the upper portion 14b of the wiring housing 14c oppose each other.

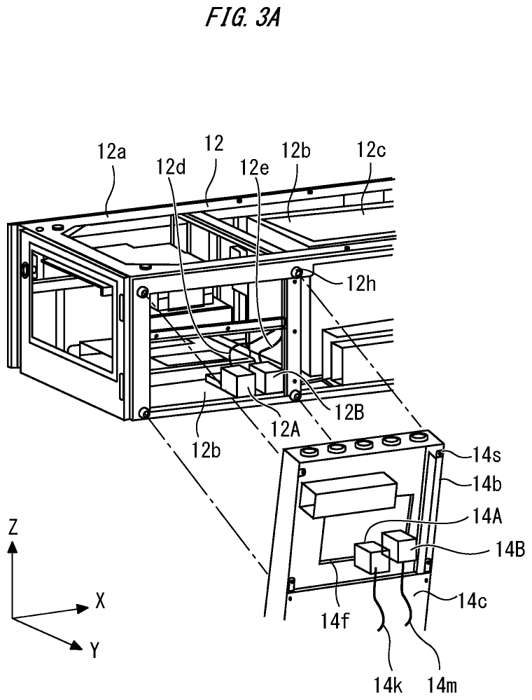

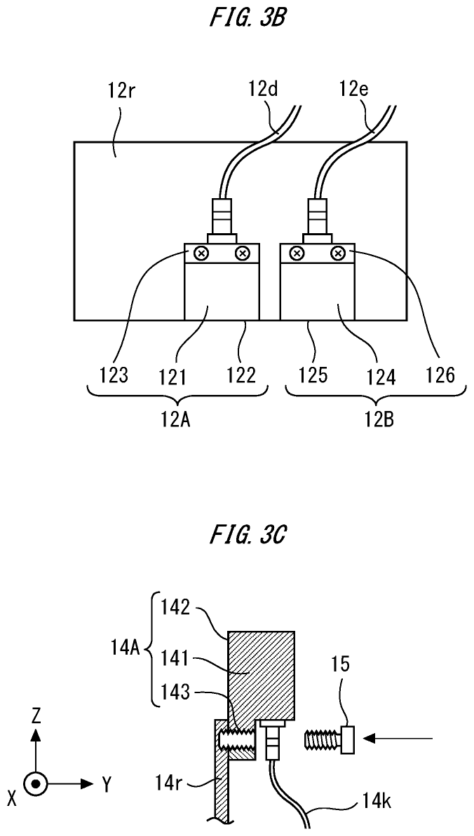

FIG. 3A is a diagram illustrating an example of a wiring method to be used when the ELEC BOX 12 and the EFEM 14 are docked to each other. The ELEC BOX 12 is provided with two first communication devices 12A and 12B. The first communication devices 12A and 12B are not outside a housing of the ELEC BOX 12 but are positioned at an edge of the housing. The first communication devices 12A and 12B are respectively connected to wirings 12d and 12e. According to one example, the first communication devices 12A and 12B transmit and receive data to and from a controller and receive power therefrom, respectively, through the wirings 12d and 12e.

The upper portion 14b of the wiring housing 14c is provided with two second communication devices 14A and 14B. The second communication devices 14A and 14B are not outside a housing of the wiring housing 14c but are positioned at an edge of the housing. The second communication devices 14A and 14B are respectively connected to wirings 14k and 14m. According to one example, the second communication devices 14A and 14B transmit and receive data to and from each of the devices and provide power thereto, respectively, through the wirings 14k and 14m.

FIG. 3B is a plan view of the first communication devices 12A and 12B illustrated in FIG. 3A and their respective vicinities. According to one example, the first communication device 12A includes a main body section 121, a first non-contact surface 122, and a screwing section 123. The first non-contact surface 122 is brought close to a non-contact surface of another communication device, thereby making it possible to perform non-contact communication between the two communication devices. The first communication device 12A can be fixed to a fixing plate 12r by being screwed into the fixing plate 12r after a screw is passed through the screwing section 123. Similarly, the first communication device 12B includes a main body section 124, a first non-contact surface 125, and a screwing section 126. The first non-contact surface 125 is brought close to a non-contact surface of another communication device, thereby making it possible to perform non-contact communication between the two communication devices. The first communication device 12B can be fixed to the fixing plate 12r by being screwed into the fixing plate 12r after a screw is passed through the screwing section 126. In an example illustrated in FIG. 3B, the two first communication devices 12A and 12B are screwed into the fixing plate 12r. The fixing plate 12r is a L-shaped sheet metal, for example. When the fixing plate 12r is screw-fixed, for example, to anywhere in the ELEC BOX 12, respective positions of the first communication devices 12A and 12B in the ELEC BOX 12 can be fixed.

FIG. 3C is a diagram illustrating a specific example of the second communication device 14A. According to one example, the second communication device 14A includes a main body section 141, a second non-contact surface 142, and a screwing section 143. The second non-contact surface 142 is brought close to a non-contact surface of another communication device, thereby making it possible to perform non-contact communication between the two communication devices. The second communication device 14A can be fixed to a fixing plate 14r by being screwed into the fixing plate 14r after a screw 15 is passed through the screwing section 143. According to one example, the second communication device 14B has the same configuration as that of the second communication device 14A, and can be screw-fixed to the fixing plate 14r. When the fixing plate 14r is screw-fixed, for example, to anywhere in the wiring housing 14c, respective positions of the second communication devices 14A and 14B in the wiring housing 14c can be fixed.

In FIG. 3A, the fixing of the ELEC BOX 12 and the EFEM 14, described above, is illustrated. In this example, the ELEC BOX 12 and the EFEM 14 are fixed to each other by passing a screw 14s into each of four corners of the upper portion 14b and screwing the screw 14s into a screw hole 12h provided in a housing of the ELEC BOX 12. Screw-fixing at other positions can also be added. According to another example, the ELEC BOX 12 and the EFEM 14 are screwed into and fixed to each other at the other positions.

When the respective first non-contact surfaces of the first communication devices 12A and 12B are exposed from the opening 12b, and the respective second non-contact surfaces of the second communication devices 14A and 14B are exposed from the opening 14f, to dock the ELEC BOX 12 and the EFEM 14 to each other, the one first non-contact surface can be brought into non-contact with and close to the one second non-contact surface.

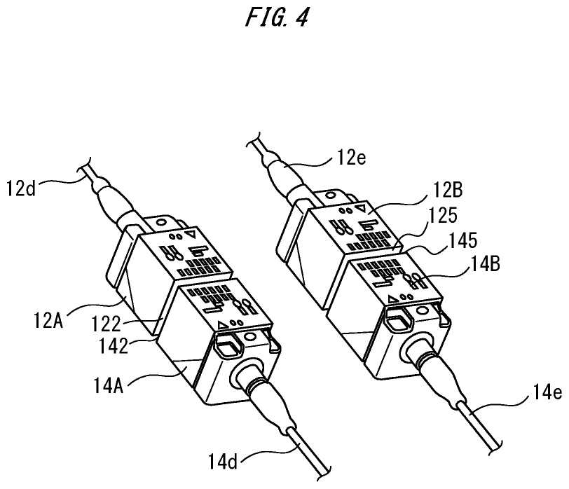

FIG. 4 is a diagram illustrating a state where the first non-contact surface and the second non-contact surface are brought into non-contact with and close to each other. More specifically, the first communication devices 12A and 12B and the second communication devices 14A and 14B with the ELEC BOX 12 and the EFEM 14 docked to each other are illustrated. The first non-contact surface 122 and the second non-contact surface 142 are close to each other until a distance therebetween is several millimeters, for example, although not in contact with each other. The first non-contact surface 125 and the second non-contact surface 145 are close to each other until a distance therebetween is several millimeters, for example, although not in contact with each other. According to one example, a distance between the two non-contact surfaces can be set to 5 mm or less. This makes it possible to transmit and receive data and transmit and receive power between the first communication device 12A and the second communication device 14A, and makes it possible to transmit and receive data and transmit and receive power between the first communication deice 12B and the second communication device 14B. According to one example, when such non-contact communication devices are provided, a wiring by a physical wire between the ELEC BOX 12 and the EFEM 14 can be eliminated. In this case, a docking operation itself between the ELEC BOX 12 and the EFEM 14 also serves as an operation for bringing paired communication devices close to each other. When the docking operation is completed, the ELEC BOX 12 and the EFEM 14 automatically enter a state where they are wired by the non-contact communication devices.

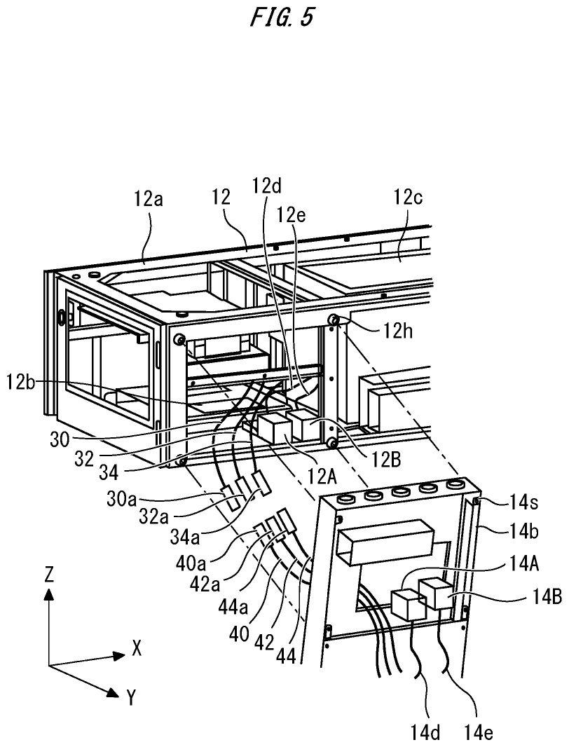

FIG. 5 is a diagram illustrating a method for connecting the ELEC BOX 12 and the EFEM 14 to each other according to another example. In the example illustrated in FIG. 5, when the ELEC BOX 12 and the EFEM 14 are docked to each other, a wired connection is provided therebetween. As a part of the ELEC BOX 12, there are wirings 30, 32, and 34 connected to a controller or a power supply and connectors 30a, 32a, and 34a provided in their respective end portions. On the other hand, as a part of the EFEM 14, there are wirings 40, 42, and 44 connected to a controller or a power supply and connectors 40a, 42a, and 44a provided in their respective end portions. At the time of an operation for docking the ELEC BOX 12 and the EFEM 14 to each other by screwing or the like, the connectors 30a, 32a, and 34a are respectively connected to the connectors 40a, 42a, and 44a. In the example illustrated in FIG. 5, both non-contact communication or power supply and wired communication or power supply can be performed between the ELEC BOX 12 and the EFEM 14. Generally, the non-contact communication is suitable for data communication and supply of small power. On the other hand, a hard-wired wiring can be used for power supply having a relatively large current value. If a driving-system device exists in one of two blocks to be docked to each other, for example, the hard-wired wiring is responsible for power supply to the driving-system device. Examples of the driving-system device include a motor for an elevating machine in a load lock chamber and a wafer conveyance robot in a WHC. However, if a current value that can be provided by non-contact communication devices is high, the hard-wired wiring can be completely eliminated. Although a process module referred to as a reactor chamber includes a rotation arm, a susceptor motor, or a gate valve, power supplies can be individually ensured therefor.

When at least two non-contact communication devices are brought close to each other at the time of docking between blocks, as described above, wireless communication can be performed between the blocks. This enables hard-wired wirings between the blocks to be eliminated or reduced. For example, at least hard-wired wirings for data communication applications other than power supply can be all respectively replaced with non-contact communication devices. This idea is applicable to not only the specific two blocks but also all blocks in the semiconductor manufacturing apparatus. When the idea is represented in a slightly abstract manner, the hard-wired wirings can be eliminated or reduced by:
1. fixing a first communication device to a first housing while exposing a first non-contact communication surface from the first housing and fixing a second communication device to a second housing while exposing a second non-contact communication surface from the second housing, and
2. fixing the first housing to the second housing while making the first non-contact communication surface and the second non-contact communication surface oppose each other without bringing the surfaces into contact with each other.

When the communication devices are respectively screwed into a first fixing plate in the first housing and a second fixing plate in the second housing, the communication devices can be stably held. According to one example, when the two blocks are assembled by screwing, two non-contact surfaces can be brought close to each other to a wirelessly communicable degree. In other words, the two blocks need not be precisely aligned with and docked to each other. According to one example, use of a positioning pin when blocks are docked to each other contributes to a positioning accuracy being ensured without deteriorating operability.

The first communication device and the second communication device to be brought close to each other may be configured such that transmission and receiving of data and supply of power in a non-contact manner are possible, may be configured such that only transmission and receiving of data in a non-contact manner are possible, or may be configured such that only supply of power in a non-contact manner is possible. In the example illustrated in FIG. 3A, no wired connection exists between two sub-assemblies. On the other hand, in the example illustrated in FIG. 5, there is a power supply wiring that connects two sub-assemblies in a wired manner. It can be determined which of the sub-assemblies is to be adopted depending on functions respectively required for the sub-assemblies.

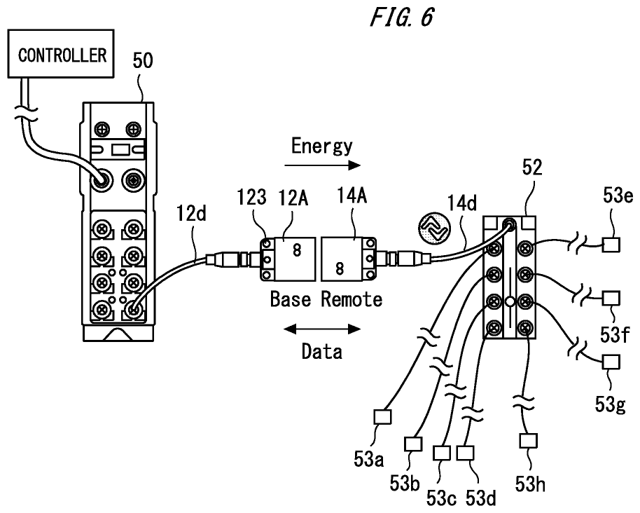

FIG. 6 is a diagram illustrating an example in which non-contact communication devices are applied to an IO-Link system. A plurality of sensors 53a, 53b, 53c, and 53d and a plurality of actuators 53e, 53f, 53g, and 53h are respectively connected to a second communication device 14A via a hub 52. An example of the plurality of sensors is a displacement sensor, a pressure sensor, or a photoelectric sensor. An LED can be connected to the second communication device 14A in addition to or instead of the sensors. Any IO-Link device can be connected to the second communication device 14A. An IO-Link master 50 is connected to a first communication device 12A. The IO-Link master 50 is a terminal unit that receives a signal of the IO-Link device. The IO-Link master 50 is connected to a controller 51 such as a PLC. As apparent from FIG. 6, information obtained from a sensor or the like is acquired, power is supplied to a sensor or the like, setting information is transmitted to the IO-Link device, and an TO check is performed via the first communication device 12A and the second communication device 14A, respectively, as the non-contact communication devices. Such an IO-Link system can be provided in any two blocks in a semiconductor manufacturing apparatus.

When a plurality of first communication devices and a plurality of second communication devices, described above, are provided in the semiconductor manufacturing apparatus, approximately 150 hard-wired wirings, which have been required in an entire docking operation, can be reduced to approximately 10 hard-wired wirings, for example.

The examples illustrated in FIGS. 2 to 6 make it possible to perform non-contact communication between the ELEC BOX 12 having a first housing storing a module controller and the EFEM 14 having a second housing storing a wafer conveyance robot and a fan filter unit. However, the above-described non-contact communication or power supply can be applied to other two blocks in the semiconductor manufacturing apparatus.

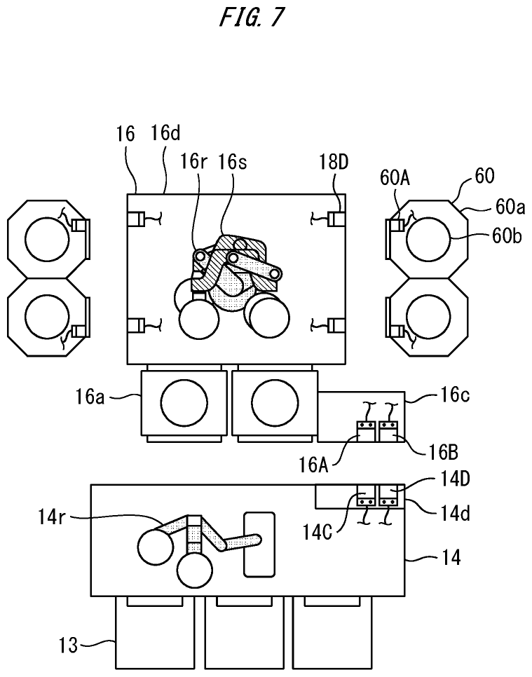

FIG. 7 is a diagram illustrating an example in which non-contact communication devices are respectively provided in other two blocks. A load port 13 is connected to an EFEM 14. A lower portion 14d of a wiring housing 14c in the EFEM 14 is provided with first communication devices 14C and 14D. The EFEM 14 includes a first housing and a fan filter unit provided therein. A wiring housing 16c as a part of a center module 16 is provided with two communication devices 16A and 16B. A first WHC 16b is provided with two wafer conveyance robots 16s and 16r, for example. The center module 16 is a sub-assembly including a second housing, a load lock chamber, a first WHC, and a wafer conveyance robot. When the EFEM 14 and the center module 16 are docked to each other, the first communication device 14C and the second communication device 16A come close to each other to a communicable degree, and the first communication device 14D and the second communication device 16B come close to each other to a communicable degree. According to one example, the EFEM 14 and the center module 16 can be brought into a communicable state without requiring a wired connection when screw-fixed to each other. According to another example, a hard-wired wiring for power supply can be added, as described with reference to FIG. 5.

Further, a second communication device 60A and a first communication device 18D can be brought into a non-contact communicable state by providing a reactor chamber 60 with a second communication device 60A, providing the center module 16 with a first communication device 18D, and docking the reactor chamber to the center module 16. According to one example, the first communication device 18D is connected to a PLC in a PLC BOX 18.

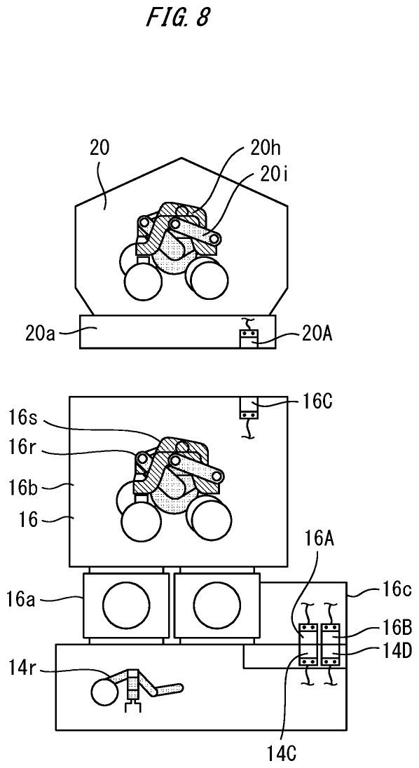

FIG. 8 is a diagram illustrating an example in which non-contact communication devices are respectively provided in other two blocks. A first sub-assembly includes a first housing, a first WHC 16b, and first wafer conveyance robots 16s and 16r in the first WHC 16b. A second sub-assembly includes a second housing, a second WHC 20b, and second wafer conveyance robots 20h and 20i in the second WHC 20b. FIG. 8 indicates that a first communication device 16C is provided in a center module 16, and a second communication device 20A is provided in a pass-through chamber 20a. According to one example, when the center module 16 and a rear module 20 are screw-fixed to each other, the first communication device 16C and the second communication device 20C come close to each other and can be brought into a communicable state without requiring a wired connection. According to another example, a hard-wired wiring for power supply can be added, as described with reference to FIG. 5.

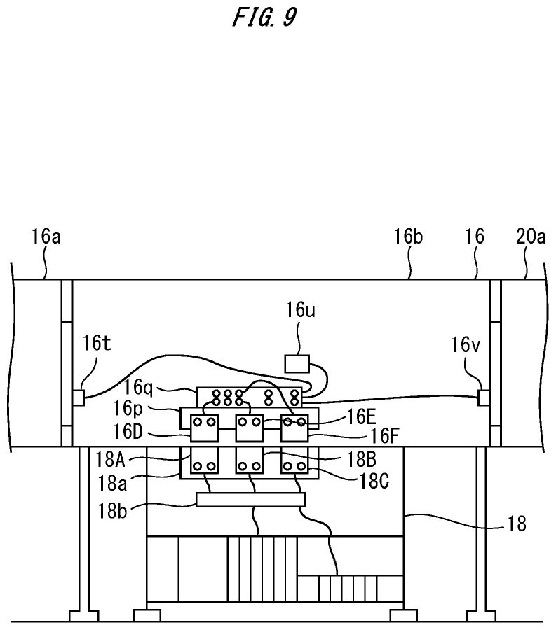

FIG. 9 is a diagram illustrating an example in which non-contact communication can be performed between a PLC BOX 18 and a center module 16. According to one example, there are an IO-Link master 18b connected to a PLC and first communication devices 18A, 18B, and 18C connected to the IO-Link master 18b in the PLC BOX 18. There are second communication devices 16D, 16E, and 16F, a hub 16g connected thereto, and sensors 16t, 16v, and 16u connected to the hub 16g in a first WHC 16b. When a housing of the PLC BOX 18 is fixed with a screw, for example, to a housing of the center module 16, the first communication devices 18A, 18B, and 18C respectively come close to the second communication devices 16D, 16E, and 16F, and enter a non-contact communicable state.

When both a utility box 22 and a rear module 20 are respectively provided with communication devices, and are docked to each other, the two communication devices are brought close to each other to be non-contact communicable to each other.

Any two blocks can be made non-contact communicable to each other by any one of some non-contact communication methods, described above. For example, data may be transmitted and received in a non-contact manner by two communication devices between a box having any electrical device and a conveyance module having a wafer conveyance robot and a chamber. According to one example, a remote IO unit may be connected to the first communication device, for example, using the above-descried technique. For example, the controller 12a illustrated in FIG. 1 corresponds to the remote IO unit.

What is claimed is:

1. A semiconductor manufacturing apparatus comprising:
a first housing;
at least one first communication device fixed to the first housing and having a first non-contact communication surface exposed from the first housing;
a second housing fixed to the first housing; and
at least one second communication device fixed to the second housing and having a second non-contact communication surface exposed from the second housing,
wherein the first non-contact communication surface and the second non-contact communication surface oppose each other without contacting each other.

2. The semiconductor manufacturing apparatus according to claim 1, further comprising
a first fixing plate provided in the first housing; and
a second fixing plate provided in the second housing,
wherein the at least one first communication device is screwed into the first fixing plate, and the at least one second communication device is screwed into the second fixing plate.

3. The semiconductor manufacturing apparatus according to claim 1, wherein the at least one first communication device comprises a plurality of first communication devices, and the at least one second communication device comprises a plurality of second communication devices.

4. The semiconductor manufacturing apparatus according to claim 1, further comprising a sensor connected to the at least one second communication device.

5. The semiconductor manufacturing apparatus according to claim 4, wherein the sensor is a displacement sensor, a pressure sensor, or a photoelectric sensor.

6. The semiconductor manufacturing apparatus according to claim 1, further comprising an LED connected to the at least one second communication device.

7. The semiconductor manufacturing apparatus according to claim 1, further comprising an actuator connected to the at least one second communication device.

8. The semiconductor manufacturing apparatus according to claim 1, further comprising
an IO-Link master connected to the at least one first communication device, and
a sensor connected to the at least one second communication device.

9. The semiconductor manufacturing apparatus according to claim 1, further comprising
a module controller provided in the first housing,
a wafer conveyance robot provided in the second housing, and
a fan filter unit provided in the second housing.

10. The semiconductor manufacturing apparatus according to claim 1, further comprising
a fan filter unit provided in the first housing, and
a sub-assembly including the second housing, a load lock chamber, a first wafer handling chamber, and a wafer conveyance robot.

11. The semiconductor manufacturing apparatus according to claim 1, further comprising
a programmable logic controller provided in the first housing,
wherein the at least one first communication device is connected to the programmable logic controller.

12. The semiconductor manufacturing apparatus according to claim 1, further comprising
a first sub-assembly including the first housing, a first wafer handling chamber, and a first wafer conveyance robot in the first wafer handling chamber, and
a second sub-assembly including the second housing, a second wafer handling chamber, and a second wafer conveyance robot in the second wafer handling chamber.

13. The semiconductor manufacturing apparatus according to claim 1, further comprising
a remote IO unit provided in the first housing, and
a sub-assembly including the second housing, a wafer handling chamber, and a sensor,
wherein the at least one first communication device is connected to the remote IO unit.

14. The semiconductor manufacturing apparatus according to claim 1, wherein the first housing and the second housing are screw-fixed to each other.

15. The semiconductor manufacturing apparatus according to claim 1, wherein
the at least one first communication device and the at least one second communication device are configured to be capable of transmission and receiving of data and supply of power in a non-contact manner, and
no wired connection exists between a first assembly including the first housing and a second sub-assembly including the second housing.

16. The semiconductor manufacturing apparatus according to claim 1, further comprising a power supply wiring that connects a first sub-assembly including the first housing and a second sub-assembly including the second housing in a wired manner.

17. A semiconductor manufacturing apparatus comprising:
a sensor;
non-contact communication devices that transmit and receive information obtained by the sensor in a non-contact manner;
a wafer conveyance robot; and
a wafer processing chamber.

18. The semiconductor manufacturing apparatus according to claim 17, further comprising
a box including an electrical device, and
a conveyance module including a wafer conveyance robot and a chamber,
wherein the non-contact communication devices are arranged to transmit and receive data in a non-contact manner between the box and the conveyance module.

19. The semiconductor manufacturing apparatus according to claim 18, wherein the box and the conveyance module are screwed into and fixed to each other.

20. The semiconductor manufacturing apparatus according to claim 18, wherein the electrical device is a module controller or a programmable logic controller.
